(19) United States
(12) Patent Application Publication
(10) Pub. No.: US 2017/0350535 A1
(43) Pub. Date: Dec. 7, 2017

(54) METHODS OF FAULT DETECTION FOR SOLENOID VALVES

(71) Applicants: Noel Jordan Jameson, Silver Spring, MD (US); Michael G. Pecht, College Park, MD (US)

(72) Inventors: Noel Jordan Jameson, Silver Spring, MD (US); Michael G. Pecht, College Park, MD (US)

(21) Appl. No.: 15/466,812

(22) Filed: Mar. 22, 2017

Related U.S. Application Data
(60) Provisional application No. 62/311,676, filed on Mar. 22, 2016.

(51) Int. Cl. F16K 37/00; G01R 31/06; F16K 31/06; F16H 61/12; G01R 31/28; G01R 19/25

(52) U.S. Cl. CPC F16K 37/0075; F16K 31/0675; F16H 61/12; G01R 31/06; F16H 2061/1216; G01R 19/2506; F16H 2061/1264; G01R 31/2829

(57) ABSTRACT

This invention provides two methods for detecting mechanical or electrical faults in a solenoid valve. In the first method, a force sensor is placed in the valve in such a way as to detect changes in the impact force of the plunger against the solenoid valve body or coil housing (depending upon the direction of movement of the plunger upon application of the electric current/magnetic field). A second method is provided which makes use of an accelerometer placed in such a way as to detect changes in the response of the plunger to the application of the magnetic field.

### FIELD OF INVENTION

The present invention relates to methods for monitoring the health (degradation) conditions of a solenoid valve by measuring various operational parameters that can be associated with changes in performance. More particularly it relates to the placement and use of various sensors such as a force sensor and/or an accelerometer for detecting changes in travel parameters of the solenoid piston as the valve is actuated.

### BACKGROUND OF THE INVENTION

Solenoid valves, or solenoid-operated valves (SOVs), are pieces of equipment that are widely used in a variety of industries to dose, allocate, shut off, or combine fluids. While in use, solenoid valves experience stresses arising from the process fluid(s), ambient environment, and Joule heating of the electromagnetic coil. Some mechanisms of failure for solenoid-operated valves are described in detail below.

The plunger is responsible for allowing or preventing the flow of process fluid through the solenoid valve. They are designed in the at-rest or normal position to be either in the fully open or closed state (referred to as “normally open” or “normally closed”), the selection of the type of valve (open or closed) dependent upon the intended use, e.g., either to meter a flow of liquid, or disrupt and otherwise stop what would otherwise be a continuous liquid flow.

In common designs, the plunger is exposed to the process fluid. The plunger is typically made of a soft ferromagnetic material in order to perform the functions necessary for the valve. The most common material used for this purpose is stainless steel 430F, a low-carbon, high-chromium stainless steel that was developed specifically for solenoid plunger applications in corrosive environments. As the plunger is often exposed to the process fluid, corrosion frequently acts on the plunger material. Additionally, the plunger is in contact with the plunger tube, which induces friction, wear, and material loss. The increased friction, wear, and material loss will be evidenced by stick slip behavior or a failure to fully seal the valve when closed. The plunger is also exposed to the magnetic field created by the electrical coil. Prolonged exposure to this field can result in permanent magnetization of the plunger, resulting in improper behavior of the plunger, and improper metering of the process fluid. Any changes in the behavior of the plunger can result in changing the overall response of the plunger to the magnetic field, in addition to the impact force of the plunger when it reaches its operational position.

The plunger tube functions as a barrier between the plunger and the electrical coil. It protects the coil from the process fluid and directs the magnetic flux into the plunger instead of around the plunger. Most designs call for the plunger tube to be constructed of aluminum or paramagnetic stainless steel. (A ferromagnetic plunger tube would provide a shunt path for the magnetic field lines, which would reduce the efficiency of the SOV.) Aggressive process fluids and friction produced by interaction with the moving plunger result in wear of the plunger tube. This produces wear particles that can inhibit the movement of the plunger. When the plunger is exposed to these inhibitions, it will respond differently to the application of the magnetic field. These changes in response can be detected as changes in the impact force of the plunger and in the acceleration signal of the plunger.

The electromagnetic coil is responsible for producing the magnetic field that magnetizes the plunger and produces the necessary motion of the valve. The wire used is generally referred to as magnet wire and is usually constructed of copper. Generally, within the solenoid valve field, there are three main types of insulation used to coat the wire. Class E insulation is rated for temperatures up to 120° C.; class F is rated for temperatures up to 155° C.; and class H is rated for temperatures up to 180° C. Electrical coil construction is generally divided into two methods: tape-wrapped coils and encapsulated coils. Tape-wrapped coils are manufactured by winding wire around a spool or bobbin, and then protecting the winding with insulation tape. Encapsulated coils also have a wire wound around a spool or bobbin, but the wire is then encapsulated or molded over with a suitable resin.

As an electric current is passed through the wire, Joule heating causes an increase in the wire temperature. If the temperature is too great, the dielectric material between the wires could degrade and fail, and then, two neighboring wires would form an electrical connection, producing a turn-to-turn or layer-to-layer short. These shorts would cause the coil resistance to decrease, thus pulling a greater current into the valve. At the location of the short, a hot spot can form, where the local temperature is great enough to cause the wire to burn out, resulting in an open, circuit. Corrosion can also play a role in the failure of the electrical coil by causing necking and loss of conducting material in the wire. As faults develop in the electromagnetic coil, the intensity of the magnetic field will deviate from the designed value. This deviation will affect the force with which the plunger impacts at its operating position, which can be detected through the use of a force sensor; and the response of the plunger to the application of the magnetic field, which can be detected with the use of an accelerometer.

Prior to the instant invention, there have been efforts to provide health-monitoring benefits for valves in general, some of which can be applied in solenoid valves. One of the more widely used techniques is called partial stroke testing. In this method, a position sensor is used to detect changes in the position of the plunger, which can provide insight into faults that may be present in the valve [1]-[3]. Some prior technology concerning partial stroke testing can be found in references [4]-[6]. However, one drawback is that many solenoid valves are small, and therefore may not have enough space inside to accommodate a position sensor. Further, as position of the plunger must be mathematically differentiated twice in order to compute acceleration, any faults that are sensitive to acceleration of the plunger may be overlooked due to numerical approximations.

In 1992, Oak Ridge National Laboratory conducted a series of experiments aimed at discovering methods of performing health monitoring of solenoid valves [7]-[9]. The methods discussed include the monitoring of coil inductance during actuation, equivalent circuit modeling of the electromagnetic coil, and monitoring of current through the electromagnetic coil while ramping up the voltage. These methods were capable of providing health information, but do not provide online monitoring capabilities.

There are other technologies aimed at performing diagnostics on solenoid valves, such as one measuring valve current as a proxy for understanding the movement of the plunger and electromagnetic coil health [10], measurement of acoustic and electric field signals as the plunger moves between its fully open to fully closed position to ascertain the change of state of the SOV plunger [11], a system to monitor the phase difference between the voltage and current applied to a solenoid valve in order to monitor the position of the SOV plunger [12], and control of an SOV, given that the SOV is characterized as faulty by a logic solver [13].

Though the above-described techniques are useful, they all suffer from the inability to measure degradation, which is the basis for prognostics. By measuring the degradation, the user is given the ability to perform various logistics, reliability, safety and maintenance actions, such as replacing the valve at a convenient (or safe) time and when the valve has degraded but not necessarily failed to perform its intended function.

### SUMMARY OF THE INVENTION

By way of this invention, two methods are provided for monitoring the health of solenoid valves. In a first embodiment, a force sensor is placed at a location in the valve so as to capture the impact force of the plunger against the portion of the valve that absorbs the impact when the electromagnetic coil is energized. This method can be used to detect faults in the valve, such as contamination/corrosion of the plunger or plunger tube, degradation of the electromagnetic coil, or degradation of the seal material. In a second embodiment, an accelerometer is placed at a location which may be exterior of the valve where it can capture the motion of the plunger when the electromagnetic coil is energized. In an embodiment, a partial stroke test is employed to test the health of the valve assembly. One advantage of such a partial stroke test is that it can be conducted without significantly impeding the flow of liquid through the value, so at to be minimally disruptive to an ongoing process. The acceleration signal from this test can be used to detect faults in the valve, such as contamination/corrosion of the plunger or plunger tube or degradation of the electromagnetic coil.

By means of the methods of this invention as described herein, direct measurements of the failure modes and their processes of the SOV components are taken. The use of the electric field measurement and in the case of the accelerometer the generated acoustic (i.e. vibration) signals provide indications concerning the successful actuation of the valve. While the measurement of current provides indirect measurements of the failure modes, it cannot provide an explicit understanding of the actual behavior and degradation state of the plunger. This actual behavior directly reflects the functionality of the SOV. In other words, the measurement techniques discussed herein are capable of providing not only indications of whether or not the valve is functioning, but of how well the valve is functioning, thus empowering condition-based maintenance operations.

### BRIEF DESCRIPTION OF THE DRAWINGS

The present invention is described with respect to particular exemplary embodiments thereof and reference is accordingly made to the drawings in which:

FIG. 1 is a schematic cross section illustrating a two-way normally-open solenoid valve.

FIG. 2A is a schematic illustration of a normally open valve with the sensor placed at the valve orifice.

FIG. 2B is a schematic illustration of a normally open valve with the sensor placed under the valve seal.

FIG. 3 is a schematic of a normally closed solenoid valve with placement of force sensor above the restoring spring.

FIG. 4A is a normally open solenoid valve with an accelerometer placed above the plunger outside the valve.

FIG. 4B is a normally open solenoid valve with an accelerometer placed above the plunger inside the valve.

FIG. 5 is a plot of RMS amplitude of vibration response at different voltages over a range of electrical excitation frequencies performed on a 120V/60 Hz solenoid operated valve with the accelerometer placed atop the solenoid valve as shown in FIG. 4(a).

FIG. 6 is a plot of RMS amplitude of vibration response at different electrical excitation frequencies with Vᵣₘₛ+5V performed on the 120V/60 Hz solenoid operated valve of FIG. 5 with the accelerometer placed atop, the plunger movements impeded by varying degrees to demonstrate the usefulness of the method.

FIG. 7 is a flow diagram illustrating the various process steps according to embodiments of the methods of this invention for SOV system monitoring using force sensor signals and/or vibration signals.

### DETAILED DESCRIPTION OF THE INVENTION

A general example of the embodiments of the invention is described below with reference to the accompanying drawings. The invention is not limited to the construction set forth and may take on many forms embodied as both hardware and/or software. The invention may be embodied as an apparatus, a system, a method, or a computer program. The numbers are used to refer to elements in the drawings.

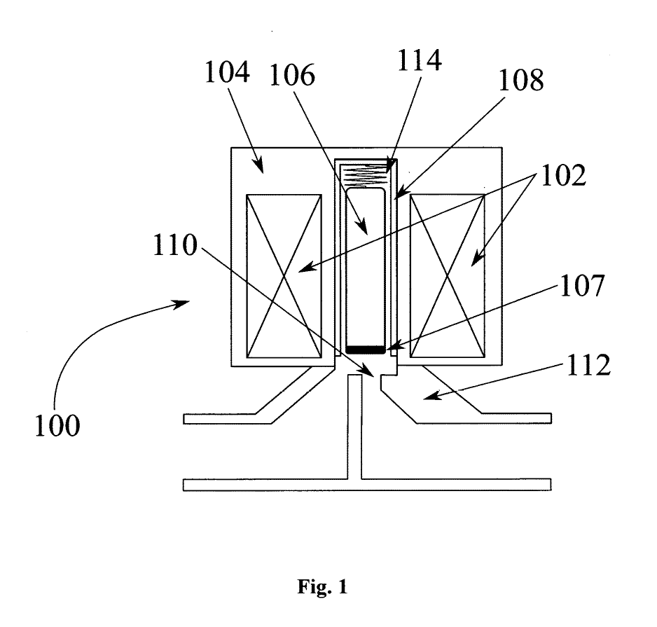

With reference to FIG. 1, a schematic of a typical solenoid operated valve is depicted, solenoid valve 100 operated by using an electromagnetic coil 102 contained with coil housing 104 to construct a magnetic field, the field acting on the ferromagnetic plunger 106, which in one embodiment may have a seal 107 affixed at its operative end. The plunger becomes magnetized and then moves within plunger tube 108 from its at-rest position (illustrated in FIG. 1) under the influence of the magnetic field until it is stopped at its operating position, such as orifice 110 of valve body 112. This operating position is held until the magnetic field is removed and the restoring spring 114 within the valve forces the plunger to move back to its at-rest position. Hence, a direct measure of the health of the valve is the force with which the plunger impacts the location of its operating position or the acceleration signal of the plunger response to the application of the magnetic field.

A new valve will have no obstacles that slow the movement of the plunger from the rest position to the operating position, and the magnetic field intensity will be such that the plunger will change position as designed. As the valve ages and degrades as a result of contamination from the process fluid or thermal loading from the environment or electromagnetic coil, the force with which the plunger impacts the location of the operating position will migrate, and this migration can be used to understand the health of the solenoid valve. Furthermore, valve degradation will result in changes to the acceleration signal, which can also or alternatively be used to provide health information for the valve.

For an SOV such as depicted in FIG. 1, according to one embodiment of the invention a force sensor 116 can be employed to monitor changes in SOV performance. A force sensor, or force transducer, is a component that converts an input mechanical force into an output electrical signal. This signal can then be sent to a data acquisition unit to record a force measurement. The functionality of the force sensor is based upon the relationship between electrical resistance and elongation, twisting, or other physical distortion of a conductive filament wire, foil, or thin film from its normal rest position.

A force sensor operates by measuring the electrical resistance of a conductive filament wire, foil, or thin film. Electrical resistance is related to the physical dimensions, and thus, when a force is applied and the dimensions of the device change, the electrical resistance is also changed. This change in electrical resistance can then be related to the applied force through an understanding of the mathematics of these relationships. Hence, a force sensor uses these known relationships to calculate the applied force given a deformation. In an embodiment, a ring-type force sensor is employed. The initial shape of the sensor is known, and thus any change in this shape will result in a change in the electrical resistance. With the relationship between the electrical resistances and the change in shape known, by measuring the electrical resistance, the applied force can be calculated. This can be done by applying a constant voltage to the sensor, measuring the current output before and after, then calculating the before and after change in resistance according to the formula V=IR. From this, changes in resistance can be converted into changes in force by standard software such as available from LabVIEW.

Force transducer systems, commonly based on strain gauge sensors or load cells, are generally inexpensive to produce. They include voltage excitation for the sensor and balancing bridge circuit, amplifier section, scaling, and conditioning electronics for the output. Analog outputs can range from direct current (DC) voltages that predominate scientific, medical, and defense applications, to standard DC current outputs of 4-20 milliamps for industrial control systems. Force transducers directly connected to computers and multiplexers can incorporate RS-232 serial interfaces, Universal Serial Bus (USB) connections, and industrial data highways such as Modbus®.

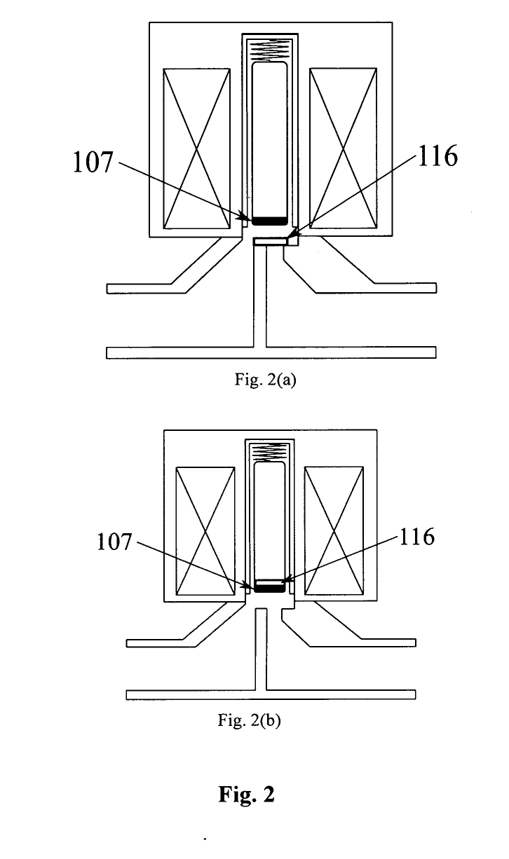

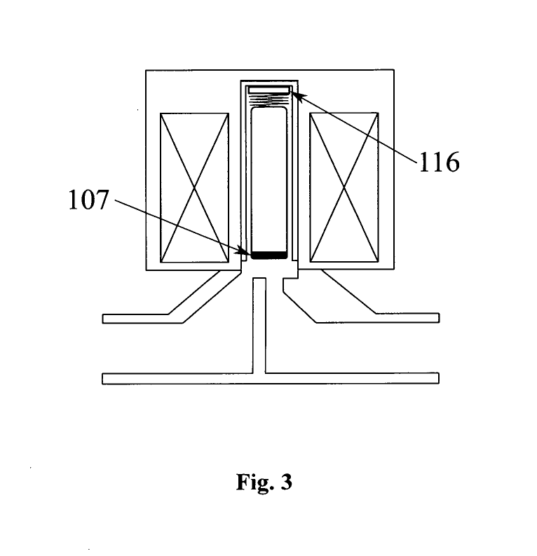

The force sensor can be placed in one of several locations, the singular requirement being that that when the plunger moves to its operating position, the force sensor will capture the impact of the plunger with the material impeding its movement at the operative position. If the operative location is at the valve orifice 110, then force sensor 116 must be of such a shape that the orifice can be sealed and opened when necessary, as shown in FIG. 2A (e.g., a ring 116 for a circular orifice). However, in another embodiment, force sensor 116 may be provided in the form, for example, of a disk if located under the seal 107, as illustrated in. FIG. 2B. If the location is at the closed end of the plunger tube, as shown in FIG. 3, then the force sensor need only be a shape and size that fits inside the plunger tube and can capture the force from restoring spring 114 against plunger tube 108. The use of the force sensor for health monitoring requires full actuation of the valve.

To deliver the required voltage to the force sensor, as well as provide an output for analysis, coaxial cable can be used, illustrated in FIG. 2 as cable 120. In one embodiment, FIG. 2A, cable 120, the cable can extend through the body of the value to the sensor. In the embodiment of FIG. 2B it can be passed through the housing of the valve, past spring 114, and then through a bore in plunger 106. In this embodiment, there must be sufficient slack in cable 120 so as to accommodate movement of the plunger from the open to closed position, when the valve is activated.

In another embodiment, wireless transmission of the force sensor output can use, in which case a voltage source such as a battery can be provided, and a wireless receiver used to detect signals from the sensor.

While the nature and operational aspects of the force sensor itself does not constitute a part of this invention, exemplary force sensors which could be useful in the practice of the invention include those provided by: HBM (http://www.hbm.com/en/0249/force-sensors-and-force-transducers), Omega (http://www.omega.com/subsection/miniature-compression-load-cells.html), or Tekscan (https://www.teksscan.com/product-group/test-measurement/force-measurement?tab=products-solutions). To address the ring-shaped force sensor necessary for some embodiments of the invention, HBM manufactures the PACEline CLP piezoelectric force sensor. The force sensors listed above are piezoelectric in their functionality and the exteriors are constructed of stainless steels. Depending upon the specific applications, it would be advantageous to ensure that the force sensor can perform at higher temperatures and humidity levels.

The use of force sensor monitoring for valve health provides several advantages. One is that proper operation of the value can be confirmed in that the force of the plunger striking the value seat is easily detected to confirm a successful opening or closing. Second, force data generated with each full stroke cycle of valve operation can be collected and recorded. As the valve continues to cycle, performance will eventually begin to degrade, the strength of the signal generated by the force sensor decreasing in response, the degree of valve performance degradation directly related to the degree of signal decrease. By such monitoring, parameters can be set as to when to replace the value as opposed instead to having to first experience value failure.

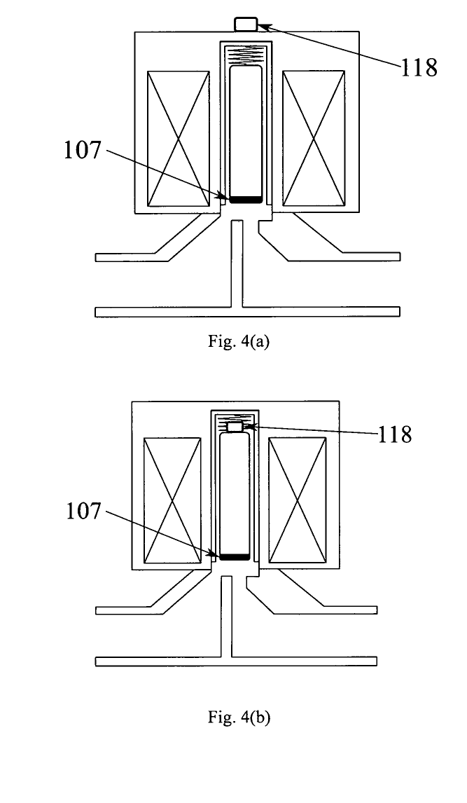

In another embodiment of the invention, an accelerometer 118 (FIG. 4) can be used instead of, or in conjunction with, the force sensor above described. An accelerometer is a device that behaves as a spring-mass-damper system. When the device experiences acceleration, the mass is displaced to a point where the spring can accelerate the mass at the same rate as the casing. The displacement is then measured to give the acceleration.

Modern accelerometers can use piezoelectric, piezoresistive, or capacitive components to convert the mechanical motion into an electrical signal. The displacement is caused by the force of the acceleration, which results in a change in the electrical characteristics of the components (piezoelectric, piezoresistive, or capacitive). By measuring the changes in the electrical characteristics of the component, the displacement and acceleration can be calculated. However, another popular accelerometer design uses micro-electromechanical systems (MEMS), which are very simple devices. Essentially, a small cantilever beam is fitted with a small mass at the end. External accelerations cause the mass to deflect from its rest position. This deflection can be measured by measuring the capacitance between the beam attached to the mass and a set of stationary beams

The accelerometer 118 can be placed above the plunger tube 108 on the exterior of the solenoid valve 100, atop the plunger where it can sense the movement of the plunger 106, as illustrated in FIG. 4A. If possible, the accelerometer 118 can alternatively be placed inside the plunger tube 108, at a location on the plunger where it is capable of directly capturing the acceleration of the plunger as it moves under the influence of the magnetic field. This setup is illustrated in FIG. 4B. In this embodiment, similarly to the force sensor, a coaxial cable can be used to deliver power to the sensor, the cable in one embodiment passed through the housing of the valve as illustrated in the figure. Hereto, in one embodiment wireless signals can be used for data transmission from the accelerometer to a receiving device.

In the embodiment where the accelerometer is placed inside the plunger tube, there will be necessary constraints on the transmission of the accelerometer signal. This transmission can be achieved in several ways. In one embodiment, the signal transmission can be built into the valve during manufacturing. As such, the accelerometer is connected to coaxial cable 120 that passes through the body of the device to an exterior connection, which can be further connected to data acquisition hardware and software. The signal can also be transmitted using an RF transmitter and receiver, which is attached to the accelerometer, and data acquisition hardware or software, respectively.

While the nature and operational aspects of the accelerometer itself does not constitute a part of this invention., exemplary accelerometers which could be useful in the practice of the invention include those provided by: PCB Piezotronics (http://www.pcb.com/imisensors/imisensors industrial accelerometers/precisio nindustrialaccelerometers), Omega (http://www.omega.com.prodinfo/accelerometers.html), or IMI (http://www.imi-sensors.com/Industrial Accelerometers). Depending upon the specific applications, it would be advantageous to ensure that the accelerometer can perform at higher temperatures and humidity levels.

In an embodiment, the natural frequency of the valve to be monitored is first established. This is accomplished by sweeping the frequency of the electrical input to the solenoid valve at a given excitation voltage. The input electrical frequency excites a current at the same frequency in the electromagnetic coil, which then causes the construction of a magnetic field at the input frequency. This magnetic field serves to force the movement of the plunger against the resistance of the restoring spring and friction in the plunger tube. Hence, when the electrical input frequency is equal to or close to the natural frequency of the plunger/plunger restoring spring/plunger tube system, the displacement of the plunger at a given voltage reaches a maximum. This displacement is detected by the accelerometer as vibration. This operation of finding the natural frequency can be performed by the manufacturer and provided as a performance specification, or determined by a user.

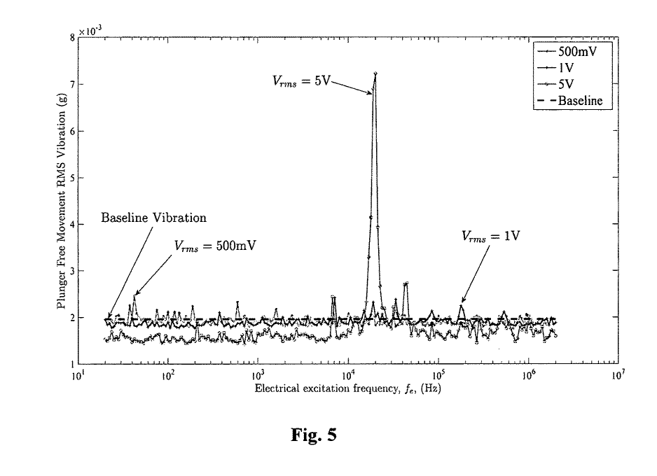

In one embodiment, in order to use the partial stroke method of this invention, the level of electromagnetic excitation must be of sufficient level to move the plunger, though it is not necessary to fully actuate the valve. An example of a preliminary study of the vibration response of the plunger system with varying electrical excitation frequencies and Root Mean Square (RMS) voltage levels is shown in FIG. 5.

With reference to the figure, the degree of excitation needed to cause a detectable movement of the plunger is determined by routine trial and error. Thus, as shown, excitation (i.e. the voltage applied to the coils) was first applied at a low (500 mV) voltage over a broad frequency range. The trial was then repeated at 1V. As can be seen from the traces, there is little detectable response at these low voltages. At 5V, however, significant movement occurred which was easily observed, the response occurring at around 20 kHz (the resonant frequency). This “minimum excitation voltage”, in fact the minimum excitation voltage necessary to produce measureable movement of the plunger, is then set as the test voltage for ongoing valve testing, with a power supply and waveform generator used at the time of testing to generate the predetermined voltage at the predetermined resonant frequency.

To confirm the proper selection of the amplitude of the excitation, the valve can then be operated at its design voltage where the plunger either seals or opens the valve, and the strength of the generated RMS vibration signal measured. The vibration signal at the minimum excitation voltage at the resonant frequency previously determined, is then compared to confirm that closure is not occurring during the partial stroke test.

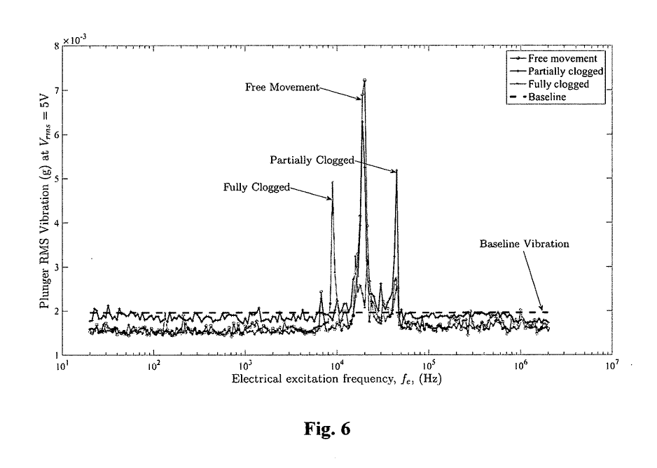

Once the parameters are established for achieving a partial stoke test, further monitoring is done activating the coil to the same level of activation. The vibration signal generated with activation of the value is then analyzed in order to perform diagnostics. Faults will emerge as shifts in features derived from frequency domain, time domain, and time-frequency domain analyses of the vibration signal. In particular, the natural frequency of the valve plunger/spring/plunger tube system will decrease in magnitude and the location of the resonance on the frequency spectrum, i.e., the frequency at which maximum vibration occurs, may shift, as is further discussed in connection with FIG. 6, discussed below.

The accelerometer must be attached to the exterior of the valve with a strong fastening substance, which in one embodiment can be Super Glue. However, if performing full actuation of the valve, it may be necessary to use a stronger attachment substance or attachment device since the force produced by the plunger movement can be quite high and may cause separation of the accelerometer. If using the accelerometer in the interior of the valve, it may be attached in a manner similar as that used when attaching to the exterior. It may be necessary to utilize a fastening substance that is resistant to the working fluid in the valve, since in many cases the plunger, and thus the accelerometer is exposed to the working fluid.

To illustrate the partial stroke method of monitoring value operation, and with reference to FIG. 5, readings were taken using a normally closed solenoid valve, rated for 120V/60 Hz operation, the valve outfitted with an accelerometer, which was placed on the exterior of the valve directly above the plunger tube as shown in FIG. 4A. The vibration signal was sampled at a rate of Fₛ=96 kHz, while the coil was excited at 201 electrical frequencies, f;, ranging from 20 Hz to 2 MHz at three RMS (root mean square) voltage levels: 500 mV, 1V, and 5V. At each value of fₑ, a 2 second vibration signal was sampled. The plot of FIG. 5 shows the relationship between the RMS of the vibration signal plotted against the frequency of the input electrical excitation. From the plot of FIG. 5 it can be gathered that the natural frequency of the spring-plunger-plunger tube system is approximately 20 kHz. Furthermore, it can be observed that an RMS voltage level of 500 mV provides very little forcing to the system. Hence, in order to apply this method, it is necessary to input a sufficient level of electrical excitation to initiate plunger movement, though it should be less than the full actuating voltage for the valve.

While the solenoid valve tested in connection with FIG. 5 was of the normally closed variety, it is to be appreciated that the methodology for establishing the resonant frequency of a normally open value would follow the same procedure.

Partial stroke testing is advantageous due to it being less disruptive than performing a full stroke of the valve. During partial stroke testing, the valve is moved a small percentage of its total stroke length, and its movement during the partial stroke can provide information about the health of the solenoid valve. In the present invention, the partial stroke distance is small due to the nature of using the smallest voltage to find the natural frequency of the plunger-restoring spring-plunger wall system. The voltage need only be large enough to locate the natural frequency, which can be as little as 8.3% of the designed voltage as shown in the example in FIG. 5 and FIG. 6. Partial stroke test has the yet additional advantage of being more sensitive because the amplitude of vibration produced by a full closure is very high, which can overshadow any information contained in the low amplitude vibration signals.

It is to be appreciated that accelerometer can also be used by itself to monitor full opening/closing of the value by measuring the impact of the plunger at it impacts the value opening (where the normal position is open), and a stop (where the normal position is closed), the force of impact confirming that the valve has fully actuated. The force of the acoustic signals can then be monitored, looking for a reduction in signal strength as indicative of a reduction of valve health.

When the normal position of the selected valve is open, the full stroke test can be combined with the partial stroke test, the later performed while the valve in in the open (not in use) position. It is to be appreciated that the disruption to a process using a normally open valve could be less than the disruption introduced into a process using a normally closed valve, where a small amount of fluid is introduced into the system by the partial opening of the valve during testing. This may not necessarily be undesirable, though depending upon the sensitivity or robustness of the process

In an embodiment, the partial stroke test can be conducted at the excitation voltage at the resonant frequency. In the experiment of FIG. 6, that was at 5 volts 4 the resonant frequency. In another embodiment, the partial stroke test can be conducted at the excitation voltage across a frequency spectrum, which can produce additional information. For a fully operational valve, at the resonant frequency, one would expect the acoustic value to be that of the valve in new or unclogged condition. A reduction in the RMS vibration value would indicate the existence of a partially clogged condition.

When debris builds in the plunger tube, or the plunger tube wall or plunger becomes rough, the movement of the plunger can be impeded. As a result, the valve may not function as desired. Two situations of plunger impedance were simulated. By placing a small piece of foam inside the plunger tube, which partially impeded the path of the plunger, a mild form of blockage was simulated. A fully impeded situation was simulated placing a greater amount of material in the plunger tube. These situations are referred to as “semi-clogged” and “fully clogged” states. The response of the valve to a Vᵣₘₛ=5V excitation with the different clogged states is shown in FIG. 6. It is easily observed that the introduction of clogging of the plunger results in a shift of the natural frequency and a reduction in the RMS magnitude of the vibration response. These are both features that can be used for health monitoring.

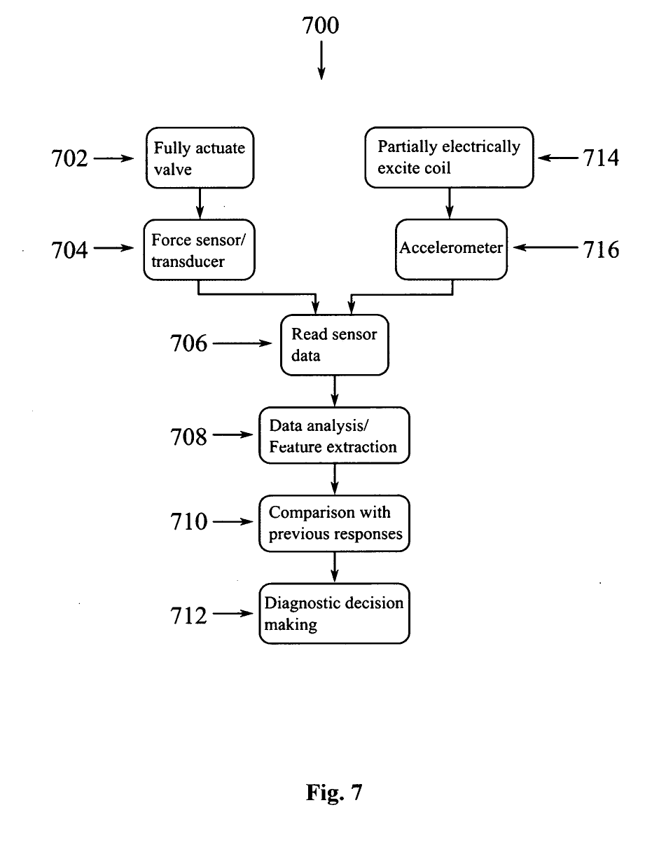

With reference now to FIG. 7, a flow diagram 700 of the process of the invention for both embodiments is depicted. In step 702 in the case of a force sensor, the valve is first fully activated. In the next step 704, the plunger impacts the force sensor, which converts the mechanical force into an electrical signal. In step 706, the sensor data is passed to a computer, which records the force measurement. The transmission of the signal is achieved through the use of data acquisition hardware, such as a data acquisition card, which can be connected first to output cable 120 and then to a computer. Step 708 consists of analyzing the data, which may or may not be necessary when using the force sensor, as the force measurement is a standalone feature that can be compared with past and future value for diagnostic purposes. In Step 710, the feature that was extracted in Step 708 is compared with past values to determine if the force measurement is decreasing. Finally, Step 712 consists of making the decision as to whether the force measurement is below a performance threshold. This threshold is typically pre-determined and is tied to the application of the valve.

The process employing an accelerometer differs only in the first two steps 714 and 716. In step 714, a low-level voltage signal is inputted to the electromagnetic coil in the valve. This can be a swept frequency signal or at a single frequency. However, it is important to measure the response of the plunger at and around the mechanical natural frequency. Further, as was mentioned previously, it is important that the electrical signal be of such a magnitude as to cause the plunger to move measurably. Then, in step 716, the accelerometer converts the mechanical vibration signal to an electrical signal that can be passed to a computer and recorded as vibration data. The feature extraction step, 708, can be more involved in this case, as the vibration signal can be statistically analyzed to get the RMS or kurtosis of the signal, or it can be analyzed in the frequency domain using a Fourier transform, resulting in a feature like peak frequency.

The foregoing detailed description of the present invention is provided for purposes of illustration and is not intended to be exhaustive or to limit the invention to the embodiments disclosed, the scope of the invention limited only the clams hereto.

What we claim is:

1. A method of detecting faults in a solenoid-operated valve (SOV) comprising:
measuring the force with which the solenoid valve plunger impacts the stopper at its operational position during the operation of the SOV to probe for faults prior to valve failure and measuring the vibration of the plunger.

2. The method of claim 1 wherein the force sensor/transducer is placed strategically, and measures the force of impact between the plunger and its stopper when the SOV is operational.

3. The method of claim 2, where the force sensor/transducer is placed at the at the point of direct impact between plunger and stopper whereby the force reading is at maximum, allowing for the quantitative analysis and comparison between recorded force values, which can consequently be used as a health monitoring metric.

4. A method for claim 2, whereby the reading from the force sensor is transformed into a health monitoring metric by considering the reading in the context of a series of prior force sensor readings that can be used to draw conclusions about the degradation mechanism(s) operating on the valve, which information can then be evaluated and used for maintenance decisions.

5. A method of detecting faults in a solenoid-operated valve (SOV) comprising:
a. Providing a solenoid value including a coil, an electromagnetic coil, a magnetizable plunger, a plunger tube and a valve body having a seal and a valve orifice,
b. Positioning an accelerometer atop the plunger tube,
c. Providing means for activating the electromagnetic coil, and means for reading the output from the accelerometer, which accelerometer outputs a reading of vibration for the plunger,
d. Applying low-level voltage signals at the resonant frequency of the plunger-plunger spring-plunger tube system, said voltage signals strong enough to cause movement of the plunger within the plunger tube, but insufficient to case travel to and closing of the valve seal,
e. Comparing the accelerometer reading for the valve for its known healthy state to the reading taken, and thereafter determining from said reading comparison the state of health of the valve.

6. The method of claim 5 wherein the accelerometer is placed internally, atop or below the plunger, such that it does not interfere with the movement and stoppage of the plunger, and outputs a reading of vibration for the plunger after the application of low-level voltage signals applied at the resonant frequency of the plunger-plunger spring-plunger tube system

7. The method for claim 5, wherein the SOV is excited by a low-level voltage signal that constructs a magnetic field that excites the plunger, provided the voltage signal is high enough.

8. The method for claim 7 wherein the vibration signal at the resonant frequency is recorded and compared against previous responses from the valve, the magnitude of the vibration response at that frequency decreasing as the valve degrades.
